(19) United States
(12) Patent Application Publication
(10) Pub. No.: US 2003/0103340 A1
(43) Pub. Date: Jun. 5, 2003

(54) EMI cancellation circuit embeded in an IC

(76) Inventor: Yu-Chiang Cheng, Taipei (TW)

Correspondence Address: BIRCH STEWART KOLASCH & BIRCH, PO BOX 747, FALLS CHURCH, VA, 22040-0747, US

(21) Appl. No.: 10/000,296

(22) Filed: Dec. 4, 2001

(51) Int. Cl. H02H 1/00; H02H 1/04; H01C 7/12; H02H 3/22; H02H 9/06; H05K 9/00

(52) U.S. Cl. 361/816

(57) ABSTRACT

An EMI cancellation circuit embedded in an IC. The EMI cancellation circuit is placed close to a noise signal source. During the manufacturing process of the IC, the EMI cancellation circuit is packaged into the IC to suppress the EMI generated by the IC.

### BACKGROUND OF THE INVENTION

1. Field of Invention

The invention relates to an EMI cancellation circuit and, in particular, to a circuit embedded in an IC for canceling the EMI.

2. Related Art

Electromagnetic phenomena are due to the dynamical exchange or variations of electric and magnetic energy and exist or present in the form of waves. The phenomenon of propagating noises within a medium due to the electromagnetic wave interactions as time varies is called EMI (Electromagnetic Interference).

The EMI generated by an interference source often interacts with the low potential levels in a circuit, gets amplified and becomes a noise signal output. The interactions can be electrostatic interaction, electromagnetic interaction, conductive interaction, etc. In most cases, there are more than one reason and more than one place to generate the EMI. In order to effectively prevent the EMI, one has to fully understand the formation reasons and possible noise signal source devices. IC's operating at high frequencies are devices that cannot be ignored.

In recent years, the information industry is prosperous. The application of IC's is also widely spread into daily life in mobile phones, personal computers, home electronics, etc. As the IC's have smaller volumes, faster speeds, and larger loops, the operating frequencies also become higher. The larger the interactions between loop signals and magnetic fields are, the more serious the EMI becomes. The reason is that as the frequency gets higher, the wavelength of the electromagnetic wave gets shorter. Therefore, there may have irregular reflections of the EMI inside the circuit, resulting in high frequency noise signals. Thus, how to efficiently eliminate the EMI produced by the noise signal sources is an important subject to be solved.

### SUMMARY OF THE INVENTION

The invention provides an EMI cancellation circuit for IC's with the problem of EMC (Electromagnetic compatibility) taken into account. Through the designs of different configuration arrangements, the disclosed EMI cancellation circuit is packaged inside the IC's during the manufacturing process of the IC's.

An object of the invention is to cancel the EMI, avoiding bad influence on the IC's due to the high frequency noises.

### BRIEF DESCRIPTION OF THE DRAWINGS

The present invention will become more fully understood from the detailed description given hereinbelow illustration only, and thus are not limitative of the present invention, and wherein:

FIG. 1A is a top view of a first embodiment of the disclosed EMI cancellation circuit for IC's;

FIG. 1B is a side cross-sectional view of a first embodiment of the disclosed EMI cancellation circuit for IC's;

FIG. 2A is a top view of a second embodiment of the disclosed EMI cancellation circuit for IC's;

FIG. 2B is a side cross-sectional view of a second embodiment of the disclosed EMI cancellation circuit for IC's;

FIG. 3A is a top view of a third embodiment of the disclosed EMI cancellation circuit for IC's;

FIG. 3B is a side cross-sectional view of a third embodiment of the disclosed EMI cancellation circuit for IC's; and

FIGS. 4A˜4F shows a packaging type of the disclosed EMI cancellation circuit for IC's.

### DETAILED DESCRIPTION OF THE INVENTION

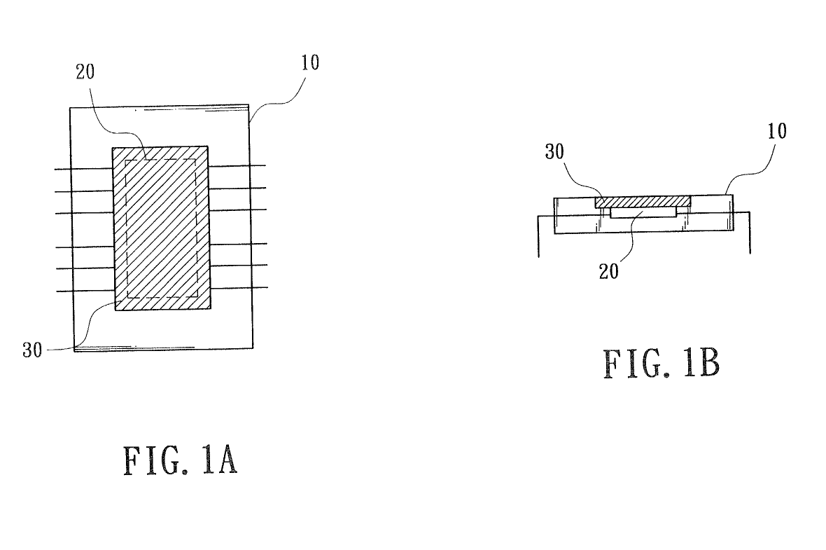

With reference to FIGS. 1A and 1B for a first embodiment of the invention, when making an IC (Integrated Circuit), a die is disposed on top of a substrate. An EMI (Electromagnetic Interference) cancellation circuit for the IC is then placed above and close to the die. After completing ILB (Inner Lead Bonding) between the die and the IC, the die and the EMI cancellation circuit are also packaged within the IC.

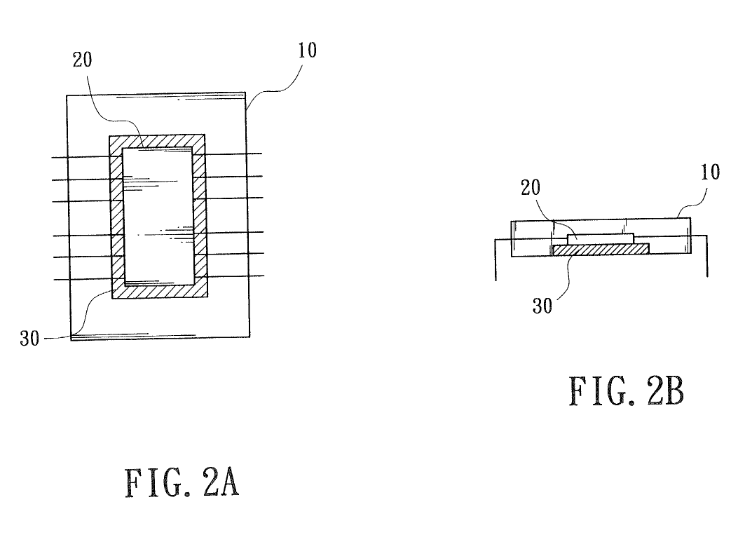

With reference to FIGS. 2A and 2B for a second embodiment of the invention, when making an IC, a die is disposed on top of a substrate. An EMI (Electromagnetic Interference) cancellation circuit for the IC is inserted between the substrate and the die. After completing ILB between the die and the IC, the die and the EMI cancellation circuit are also packaged within the IC.

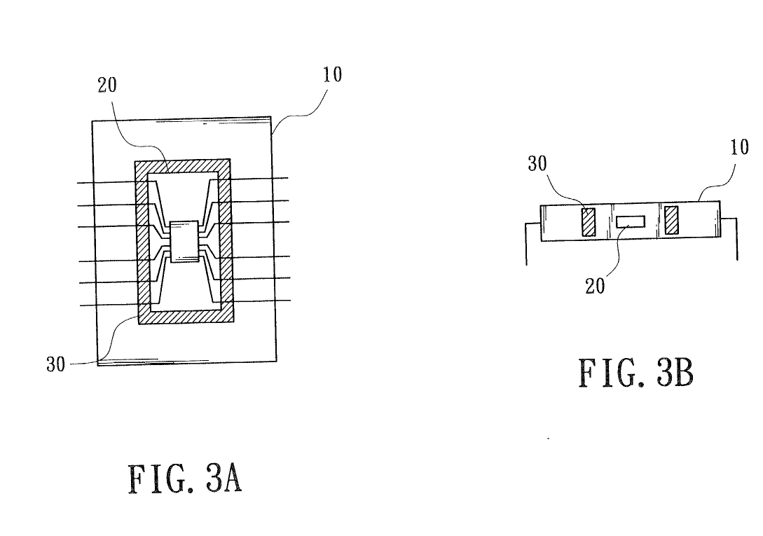

With reference to FIGS. 3A and 3B for a third embodiment of the invention, when making an IC, a die is disposed on top of a substrate. An EMI (Electromagnetic Interference) cancellation circuit for the IC is installed around the die. After completing ILB between the die and the IC, the die and the EMI cancellation circuit are also packaged within the IC.

The circuits shown in FIGS. 1A and 1B, FIGS. 2A and 2B, and FIGS. 3A and 3B are essentially the same. The only difference is where the EMI cancellation circuit is installed. In FIGS. 1A and 1B, the EMI cancellation circuit is disposed above the die. In FIGS. 2A and 2B, the EMI cancellation circuit is disposed under the die. In FIGS. 3A and 3B, the EMI cancellation circuit is installed around the die. Under the condition of not influencing the signal output, the EMI cancellation circuit is designed to be around and close to the die in different ways to achieve the goal of coupling with the noise signals and suppressing the EMI.

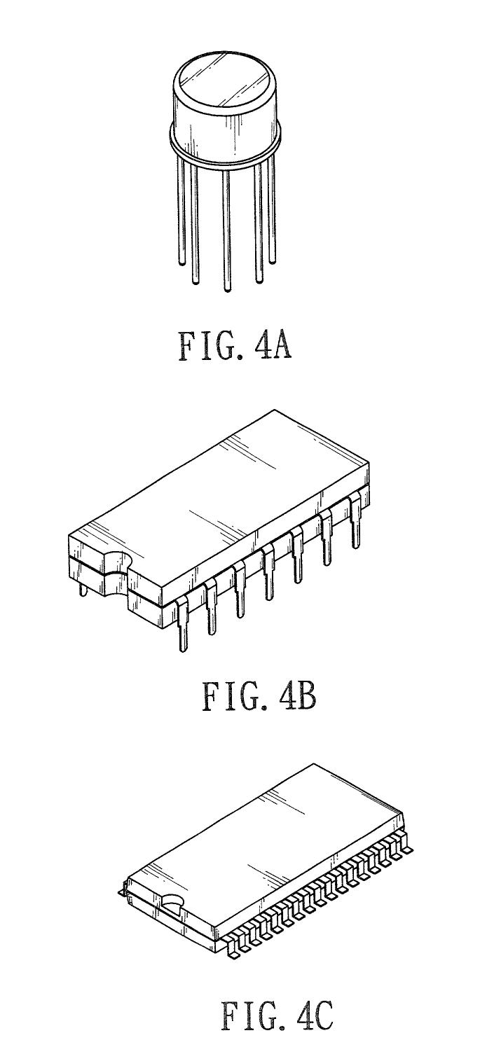

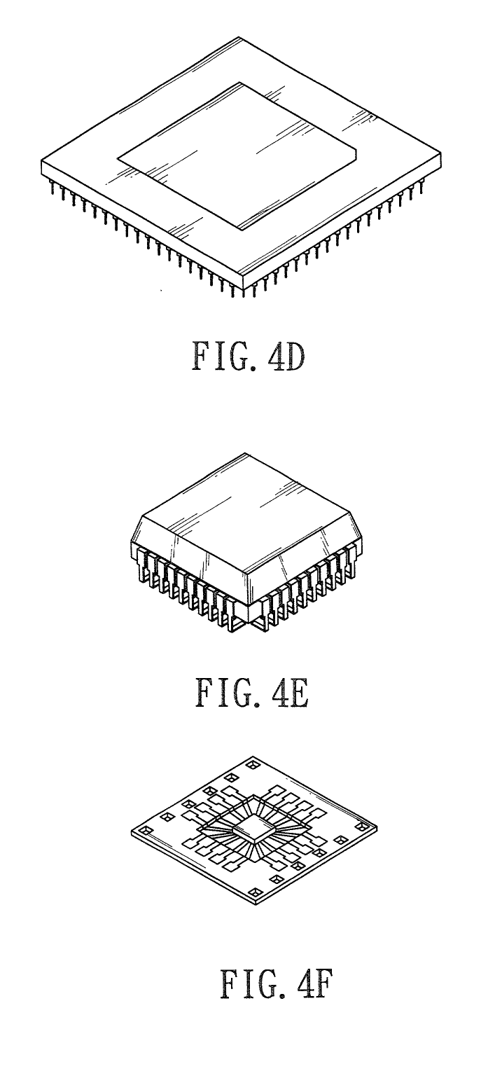

With reference to FIGS. 4A˜4F, the EMI cancellation circuit of the invention can be used in different packaging types, such as can packaging, DIP (Dual-Inline Packaging), FP (Flat Packaging), etc.

The EMI cancellation circuit embedded within the IC disclosed herein keeps a tiny distance from the IC to cancel the high frequency signals generated by the IC due to some noise signal sources. Therefore, it can ensure the normal operations of the IC.

Certain variations would be apparent to those skilled in the art, which variations are considered within the spirit and scope of the claimed invention.

What is claimed is:

1. An EMI (Electromagnetic Interference) cancellation circuit embedded within an IC (Integrated Circuit) characterized in that during the packaging procedure of the IC, the EMI cancellation circuit is disposed above and close to a noise signal source and also packaged into the IC.

2. The circuit of claim 1, wherein the IC packaging method is can packaging.

3. The circuit of claim 1, wherein the IC packaging method is DIP (Double-Inline Packaging).

4. The circuit of claim 1, wherein the IC packaging method is FP (Flat Packaging).

5. The circuit of claim 1, wherein the IC packaging method is grating array packaging.

6. The circuit of claim 1, wherein the IC packaging method is chip base packaging.

7. The circuit of claim 1, wherein the IC packaging method is belt carrier packaging.

8. An EMI (Electromagnetic Interference) cancellation circuit embedded within an IC (Integrated Circuit) characterized in that during the packaging procedure of the IC, the EMI cancellation circuit is disposed under and close to a noise signal source and also packaged into the IC.

9. The circuit of claim 8, wherein the IC packaging method is can packaging.

10. The circuit of claim 8, wherein the IC packaging method is DIP (Double-Inline Packaging).

11. The circuit of claim 8, wherein the IC packaging method is FP (Flat Packaging).

12. The circuit of claim 8, wherein the IC packaging method is grating array packaging.

13. The circuit of claim 8, wherein the IC packaging method is chip base packaging.

14. The circuit of claim 8, wherein the IC packaging method is belt carrier packaging.

15. An EMI (Electromagnetic Interference) cancellation circuit embedded within an IC (Integrated Circuit) characterized in that during the packaging procedure of the IC, the EMI cancellation circuit is disposed around and close to a noise signal source and also packaged into the IC.

16. The circuit of claim 15, wherein the IC packaging method is can packaging.

17. The circuit of claim 15, wherein the IC packaging method is DIP (Double-Inline Packaging).

18. The circuit of claim 15, wherein the IC packaging method is FP (Flat Packaging).

19. The circuit of claim 15, wherein the IC packaging method is grating array packaging.

20. The circuit of claim 15, wherein the IC packaging method is chip base packaging.

21. The circuit of claim 15, wherein the IC packaging method is belt carrier packaging.
